(19) United States
(12) Patent Application Publication
(10) Pub. No.: US 2020/0371181 A1
(43) Pub. Date: Nov. 26, 2020

(54) MAGNETIC RESONANCE UNIT AND METHOD FOR AN IDENTIFICATION OF A MAGNETIC RESONANCE UNIT

(71) Applicant: Siemens Healthcare GmbH, Erlangen (DE)

(72) Inventor: Arne Hengerer, Moehrendorf (DE)

(73) Assignee: Siemens Healthcare GmbH, Erlangen (DE)

(21) Appl. No.: 16/880,332

(22) Filed: May 21, 2020

(30) Foreign Application Priority Data
May 24, 2019 (DE) 102019207669.6

(51) Int. Cl. G01R 33/54; G01R 33/30

(52) U.S. Cl. CPC G01R 33/546; G01R 33/307

(57) ABSTRACT

Techniques are disclosed for a magnetic resonance unit which is configured for use during a magnetic resonance examination with a medical magnetic resonance device, having a housing unit, wherein the magnetic resonance unit has an information unit which is arranged on the housing unit and is acquirable by means of a magnetic resonance sequence.

### CROSS-REFERENCE TO RELATED APPLICATIONS

The present application claims the benefit of the filing date of German patent application no. DE 102019207669.6, filed on May 24, 2019, the contents of which are incorporated herein by reference in their entirety.

### TECHNICAL FIELD

The present disclosure relates to magnetic resonance units and, in particular, to the identification of a magnetic resonance unit.

### BACKGROUND

For special magnetic resonance examinations, special accessory units that must be placed and/or positioned by a user on the patient and/or on the patient support are often needed. For example, for a magnetic resonance radiotherapy examination, special positioning aids are needed for the patient. A further example of an accessory unit can be a special holder, in particular a robotic holder, for a needle intervention, which can be monitored and/or controlled by means of a magnetic resonance examination. A further example of this is an arrangement of head clamps for intraprocedural examinations in neurosurgery.

Such special magnetic resonance examinations are, however, only rarely carried out and are therefore not included in the routine work of medical personnel for the supervision of magnetic resonance examinations. For this reason, in magnetic resonance examinations of this type, undesirable delays and/or undesirably fault-laden processes can often occur.

### SUMMARY

The object underlying the present disclosure is, in particular, to support a user in the execution of special magnetic resonance examinations. The object is achieved with the features in accordance with the embodiments as described as discussed herein as well as the features recited in the claims.

The disclosure relates to a magnetic resonance unit configured for use during a magnetic resonance examination having a housing unit. According to the disclosure, the magnetic resonance unit has an information unit arranged on the housing unit and is acquirable and/or readable by means of a magnetic resonance sequence.

The magnetic resonance examination may comprise a special magnetic resonance examination. For example, a magnetic resonance examination of this type can comprise a magnetic resonance examination for neurosurgical examinations and/or for interventions and/or a radiotherapy examination, etc.

The magnetic resonance unit may comprise an accessory unit that is used during a magnetic resonance examination. For example, the magnetic resonance unit can comprise a positioning aid for a patient during a radiotherapy examination and/or a holder for an intervention, in particular a needle intervention, and/or a positioning aid, for example, a head clamp, etc. In addition, the magnetic resonance unit can comprise further accessory units deemed useful by a person skilled in the art, which can be used during a magnetic resonance examination.

For each of these special magnetic resonance examinations, a special magnetic resonance unit may be required to be able to carry out the special magnetic resonance examination efficiently. Advantageously, different magnetic resonance units are also associated, in particular, fixedly and/or unambiguously associated with different magnetic resonance examinations, so that by means of the determination and/or identification of the magnetic resonance unit, a determination and/or identification of the forthcoming magnetic resonance examination can also take place.

The magnetic resonance unit comprises a housing unit, wherein the information unit is arranged on an upper side and/or a surface of the housing unit. Advantageously, the housing unit comprises a rigid and/or stiff housing. The housing unit can also comprise a flexible housing, the shape of which is adaptable, for example, to a contour of a patient. Here, the information unit can have a structure and/or a pattern, wherein the structure and/or the pattern can be configured three-dimensional. The information unit may comprise an item of information regarding an identity of the magnetic resonance unit. In addition, the information unit is configured such that a determination and/or identification, in particular, a recognition and identification of the structure and/or of the pattern of the information unit, can take place by means of a magnetic resonance sequence. The information unit is configured so that it is readable and/or acquirable by means of a magnetic resonance sequence during a magnetic resonance scan, in particular, a special determination scan for determining and/or acquiring the information unit. The magnetic resonance sequence may comprise a magnetic resonance sequence, which is configured for acquiring an item of information of the information unit. Here, the magnetic resonance sequence of the determination scan can comprise a standard sequence, which is suitable for reading out and/or acquiring the information unit. The special determination scan for determining and/or acquiring the information of the information unit may take place in a temporal context, before the medical magnetic resonance examination on a patient, in order to be able to provide an item of information relating to the medical and/or diagnostic magnetic resonance examination for the user.

Acquirable should be understood in this regard to mean that the information unit contains at least one item of information which is determinable and/or readable by means of the magnetic resonance sequence.

By means of an embodiment according to the disclosure, the magnetic resonance unit can advantageously be determined and/or identified by means of the magnetic resonance sequence before the medical and/or diagnostic magnetic resonance examination. Thereby, a medical and/or diagnostic magnetic resonance examination correlating and/or corresponding to the magnetic resonance unit can be determined and/or specified automatically and unambiguously. The determination of the pending magnetic resonance examination enables the user, for example, a medical assistant supervising the magnetic resonance examination, to be assisted in a targeted manner. For example, information on the conduct of the pending magnetic resonance examination can thereby be output to the user by means of an output unit, in particular, a visual output unit. Therefore, an examination sequence can also be displayed to the user and/or proposals for a sequence of the individual magnetic resonance scans can be output to the user. In this way, individual, in particular special or only seldom-performed magnetic resonance examinations on the patient can be at least partially standardized. As a consequence, such a magnetic resonance examination can also be carried out by less highly trained and/or inexperienced personnel and simultaneously, a high quality of the magnetic resonance examination can be maintained.

In an advantageous development of the magnetic resonance unit, it can be provided that the information unit has a characteristic pattern. A characteristic pattern should be understood in this context to be, for instance, a pattern which has a characteristic and/or defined structure and/or a characteristic and/or defined construction, which is characteristic of a defined and/or specified embodiment of a magnetic resonance unit. For instance, for different embodiments of magnetic resonance units, the corresponding information units, in particular, the characteristic patterns of the information units, can also be differently configured, so that an unambiguous and simple association exists between a configuration of the information unit, in particular, of the characteristic pattern of the information unit, and a configuration of a magnetic resonance unit.

In an advantageous development of the magnetic resonance unit, it can be provided that the information unit comprises an encoding. The encoding can comprise, for example, a striped code and/or a barcode. In addition, the encoding can also comprise a QR encoding. The encoding may comprise a characteristic encoding which enables an unambiguous identification of a magnetic resonance unit. This embodiment of the disclosure enables a particularly easy acquisition of the identity of the magnetic resonance unit before and/or during a magnetic resonance examination, in particular, a special determination scan for determining and/or acquiring the information unit. In particular, thereby, a machine reading of the information unit can take place and thus also the magnetic resonance unit can be identified automatically by means of the encoding, in particular, the barcode.

In an advantageous development of the magnetic resonance unit, the information unit may be printed onto the housing unit. By this means, a particularly simple and rapid arrangement and/or mounting of the information unit to and/or on the magnetic resonance unit can be carried out. In addition, due to the arrangement on the housing unit of the magnetic resonance unit, a good and reliable acquisition of the information unit by means of a magnetic resonance scan, in particular, a special determination scan for determining and/or acquiring the information unit, can be ensured. Furthermore, due to the printing of the information unit onto the housing unit of the magnetic resonance unit, a subsequent arrangement and/or mounting of the information unit on a magnetic resonance unit can also take place.

The printing of the information unit onto the housing unit of the magnetic resonance unit may take place by means of a 3D printing method.

In an advantageous development of the magnetic resonance unit, it can be provided that the information unit comprises a plastics (e.g. polymer) material that is doped with particles made of, for instance, iron oxide. The plastics material can be constructed as a carrier material for the particles of iron oxide. A structure of a pattern, in particular, a characteristic pattern and/or a structure of an encoding, in particular a characteristic encoding, of the information unit can be specified and/or stipulated. By means of the magnetic resonance scan, in particular, the special determination scan for determining and/or acquiring the information unit, the relevant information of the information unit, in particular, a characteristic pattern and/or a characteristic encoding is visible due to the doping with the particles of iron oxide. By means of the particles of iron oxide, an advantageous acquisition of the information unit by means of a magnetic resonance scan, in particular, by means of a special determination scan for determining and/or acquiring the information unit can take place. In addition, by means of the plastics material, a stable holding capability and/or a stable fixing of the particles of iron oxide to the housing unit of the magnetic resonance unit can be achieved. A further advantage is that the information unit can be applied by means of a printing process, for instance a 3D printing process, onto the housing unit of the magnetic resonance unit. In an alternative embodiment of the disclosure, the plastics material can also be doped with further or alternate particles and/or elements that are visible by means of a magnetic resonance scan.

In an advantageous development of the magnetic resonance unit, it can be provided that the information unit comprises a channel system with a gadolinium solution. The channel system is printed onto the housing unit of the magnetic resonance unit. Advantageously, a 3D printing process is suitable for printing the channel system onto the housing unit of the magnetic resonance unit. The channel system can thereby advantageously comprise a plastics material, so that the channel system can be printed onto the housing unit of the magnetic resonance unit. In addition, a channel system of this type provides a high degree of stability. The channel system may comprise a closed channel system with a closable filling opening. The gadolinium solution may be advantageously arranged within the channel system.

A structure of a pattern, e.g. a characteristic pattern and/or a structure of an encoding such as a characteristic encoding, of the information unit can be defined by the channel system and/or stipulated by means of the channel system. By means of the magnetic resonance scan, the special determination scan for determining and/or acquiring the information unit, the relevant information of the information unit, e.g. a characteristic pattern and/or a characterizing encoding is visible due to the gadolinium solution. By means of the gadolinium solution, an advantageous acquisition of the information unit can take place by means of a magnetic resonance scan, such as by means of a special determination scan for determining and/or acquiring the information unit. In addition, by means of the channel system, a stable holding capability and/or a stable fixing of the gadolinium solution on the housing unit of the magnetic resonance unit can be achieved. In an alternative embodiment of the disclosure, the channel system can also comprise further or alternate solutions visible by means of a magnetic resonance scan.

In an advantageous development of the magnetic resonance unit, it can be provided that the information unit comprises two or more information elements, wherein two directly adjacent information elements have a minimum spacing. The minimum spacing may be dimensioned so that by means of a magnetic resonance scan, a special determination scan for determining and/or acquiring the information unit, the individual information elements of the information unit can be acquired in a resolved manner Thereby, the smaller the minimum spacing is between the individual information elements, the smaller the resolution of the determination scan, or the scan time for the determination scan may be extended. The minimum spacing between individual information elements may be any suitable range of values, such as 8 mm 6 mm, 4 mm, 2 mm, 1 mm, etc. In this way, a rapid and reliable acquisition and/or determination of the information unit can advantageously take place by means of a magnetic resonance scan, in particular, a special determination scan for determining and/or acquiring the information unit, and therewith an identification of the magnetic resonance unit.

In an advantageous development of the magnetic resonance unit, it can be provided that the information unit has a start element and/or a stop element. By means of the start element and/or the stop element, a reading direction for acquiring and/or determining the information unit during a magnetic resonance scan, such as a special determination scan for determining and/or acquiring the information unit, can advantageously be specified and thereby an acquisition of the information unit can be facilitated. In particular, in this way, an undesirable confusion in the allocation of information units to a magnetic resonance unit during an evaluation of determination data can be reduced and/or hindered.

In an embodiment, the start element comprises an information element which marks the beginning and/or the start of the information unit along a reading direction. The start element is readable by means of the magnetic resonance scan, in particular, the special determination scan for determining and/or acquiring the information unit. The stop element advantageously comprises an information element which marks the end and/or the termination of the information unit along a reading direction. The stop element is readable by means of the magnetic resonance scan, in particular, the special determination scan for determining and/or acquiring the information unit.

In an advantageous development of the magnetic resonance unit, it can be provided that the information unit is visually marked. Visually marked should be understood herein to mean that the information unit is arranged on the housing unit, distinguished visually, such as chromatically, from the housing unit of the magnetic resonance unit. For example, the information unit can comprise a color marking or otherwise include markings that may be viewed in a predetermined range of wavelengths. By this means that good visibility of the information unit is provided for a user. This also facilitates a user positioning the magnetic resonance unit on the patient so that the information unit can be reliably acquired by the magnetic resonance scan, in particular by a special determination scan for determining and/or acquiring the information unit.

The disclosure further relates to a magnetic resonance device with a magnetic resonance unit. The magnetic resonance device may comprise a scanner unit with a main field magnet for generating a constant and intense main magnetic field. Furthermore, the scanner unit of the magnetic resonance device comprises a gradient coil unit and a high frequency antenna unit. A patient is placed and/or moved by means of a patient positioning device of the magnetic resonance device into a patient receiving region surrounded by the scanner unit, for a medical and/or diagnostic magnetic resonance examination. The magnetic resonance unit is positioned on the patient and/or close to the patient for the medical and/or diagnostic magnetic resonance examination. The magnetic resonance unit is hereby arranged at and/or on the patient positioning device.

The advantages of the magnetic resonance device according to the disclosure substantially correspond to the advantages of the magnetic resonance unit according to the disclosure, as described in detail above. Features, advantages or alternative embodiments mentioned herein can also be transferred to the other embodiments and claimed subject matter, and vice versa.

The disclosure further relates to a method for an identification of a magnetic resonance unit with an information unit, comprising the following steps:

positioning the magnetic resonance unit on a patient positioning device of a magnetic resonance device,

positioning the patient positioning device within a patient receiving region of the magnetic resonance device such that the information unit of the magnetic resonance unit is arranged within a field of view (FOV) of the magnetic resonance device,

carrying out a determination scan for acquiring the information unit, and

evaluating determination scan data of the determination scan, wherein on the basis of the determination scan data, the magnetic resonance unit is identified.

The patient positioning device may have a patient table which is movable in the direction of a longitudinal extent of the patient table and/or in the direction of a longitudinal extent of the patient receiving region, in order to move the patient table into or out of the patient receiving region. The positioning of the magnetic resonance unit on the patient positioning device can thereby comprise a positioning of the magnetic resonance unit on and/or at the patient, in particular at or round a region of the patient to be investigated. In addition, the positioning of the magnetic resonance unit can also comprise a direct positioning at and/or on the patient table of the patient positioning device.

The positioning of the patient positioning device within the patient receiving region may comprise a positioning of the patient table within the patient receiving region. The FoV (field of view) of a magnetic resonance device may comprise a region within the patient receiving region, wherein this region comprises a main magnetic field that is generated by the main field magnet and is as homogeneous and constant as possible.

The execution of the determination scan may take place by means of a computer unit. For this purpose, the computer unit has necessary software and/or computer programs which, when executed on a processor of the computer unit, control the magnetic resonance device, in particular the scanner unit of the magnetic resonance device such that the determination scan is carried out for identification of the magnetic resonance unit, in particular automatically. The determination scan comprises a magnetic resonance scan which is configured, in particular, for acquiring determination scan data, wherein on the basis of the determination scan data, the identification of the magnetic resonance unit takes place. The determination scan is a separate magnetic resonance scan which is carried out temporally before the medical and/or diagnostic magnetic resonance examination. The determination scan can thereby generate a slice image or a plurality of slice images. The determination scan may comprise a magnetic resonance sequence which is configured to acquire individual information elements of the information unit completely and/or in a targeted manner. The magnetic resonance sequence of the determination scan can comprise a standard sequence which is suitable for reading out and/or acquiring the information unit.

The evaluation may take place by means of the computer unit, which has a special evaluation software and/or evaluation programs for this purpose. The evaluation software and/or the evaluation programs are executed on a processor of the computer unit, wherein hereby the evaluation of the determination scan data takes place. The evaluation of the determination scan data comprises a determination and/or an acquisition of an item of information contained in the information unit and/or an allocation of the information contained in the information unit to a magnetic resonance unit, in particular, an identification of the magnetic resonance unit.

By means of the method according to the disclosure, the magnetic resonance unit can advantageously be determined and/or identified by means of the magnetic resonance sequence before the medical magnetic resonance examination. On the basis of the identification of the magnetic resonance unit, a medical and/or diagnostic magnetic resonance examination correlating and/or corresponding to the magnetic resonance unit can also be unambiguously determined and/or specified. The determination of the pending medical and/or diagnostic magnetic resonance examination enables the user, for example, a medical assistant supervising the magnetic resonance examination, to be assisted in a targeted manner. For example, information on the progress of the pending medical and/or diagnostic magnetic resonance examination can thereby be output to the user by means of an output unit, in particular, a visual output unit.

In this way, individual, in particular, special or only seldom-performed medical and/or diagnostic magnetic resonance examinations on the patient can be at least partially standardized. As a consequence, such a magnetic resonance examination can also be carried out by less highly trained and/or inexperienced personnel and simultaneously, a high quality of the magnetic resonance examination can be maintained.

The advantages of the method according to the disclosure for identification of a magnetic resonance unit substantially correspond to the advantages of the magnetic resonance unit according to the disclosure, as described in detail above. Features, advantages or alternative embodiments mentioned herein can also be transferred to the other embodiments and claimed subject matter, and vice versa.

In an advantageous development of the method, it can be provided that the positioning of the patient positioning device within the patient receiving region takes place by means of a laser positioning unit of the magnetic resonance device. The laser positioning unit may be arranged on an introduction opening of the patient receiving region of the magnetic resonance device. Thereby, the laser positioning unit can be integrated within a housing of the magnetic resonance device surrounding the introduction opening. By means of the laser positioning unit, a marking, for example, a cross is thereby projected vertically downwardly onto the patient positioning device and thus marks a region on the patient positioning device and/or on an object positioned on the patient positioning device, such as the patient and/or a magnetic resonance unit. By means of the computer unit, the patient positioning device is subsequently controlled such that the region marked by the laser positioning unit is moved into the FoV of the patient receiving region and/or into the isocenter of the patient receiving region. The isocenter is that region within the patient receiving region of the magnetic resonance device, in particular, of the FoV which has the most homogenous magnetic field. This embodiment of the disclosure has the advantage that, for a user, a reliable positioning of the magnetic resonance unit within the FoV, in particular, within the isocenter of the patient receiving region can take place. In particular, in this way, unpracticed and/or inexperienced personnel can position the patient positioning device within the patient receiving region such that the magnetic resonance unit can be arranged within the FoV, in particular within the isocenter, for a determination scan.

In an advantageous development of the method, it can be provided that the evaluation of the determination scan data takes place by means of an evaluation algorithm which identifies the corresponding pattern and/or the corresponding encoding of the information unit of the magnetic resonance unit. The evaluation algorithm may comprise a pattern recognition algorithm. The evaluation algorithm, in particular, the pattern recognition algorithm, is thereby carried out automatically by the computer unit, in particular, a processor of the computer unit, during an evaluation of the determination scan data. The evaluation algorithm, in particular, the pattern recognition algorithm, can also be carried out by means of machine learning, wherein in this regard, the machine learning may be implemented on the computer unit. By means of the evaluation algorithm, in particular, the pattern recognition algorithm, an item of information contained in the information unit, in particular, an item of information contained in the characteristic pattern and/or in the characteristic encoding relating to the magnetic resonance unit, can be acquired and/or determined. Thereby, the magnetic resonance unit can be unambiguously determined and/or specified, in particular, identified. By this means, a rapid identification of the magnetic resonance unit can take place automatically and thus manual errors such as, for example, by means of a manual input, can advantageously be prevented.

In an advantageous development of the method, it can be provided that the identification of the magnetic resonance unit takes place by comparison of a determined pattern and/or a determined encoding with patterns and/or encodings stored in a database (e.g. predetermined patterns and encodings). The predetermined pattern comprises a characteristic pattern acquired and/or identified by the computer unit on the basis of the determination scan data. The predetermined encoding comprises a characteristic encoding acquired and/or identified by the computer unit on the basis of the determination scan data.

The database can be integrated as part of the computer unit. Additionally or alternatively, the database can be configured separate from the computer unit, but included as part of the magnetic resonance device. The database can also, however, be configured separate from the magnetic resonance device. A data transmission between the computer unit and the database, in particular, a database formed separately from the computer unit, can take place by means of a data transmission unit and/or a data transmission network. The database comprises an allocation of all the magnetic resonance units that are available with the corresponding characteristic patterns and/or the corresponding characteristic encodings. The comparison of a determined characteristic pattern and/or a determined characteristic encoding with patterns and/or encodings stored in a database can be carried out automatically by means of the computer unit. In particular, in this way, a rapid and unambiguous association of the determined characteristic pattern and/or the determined characteristic encoding can take place with a magnetic resonance unit and therewith an unambiguous identification of the magnetic resonance unit.

In an advantageous development of the method, it can be provided that on the basis of the identified magnetic resonance unit, an item of information is output to a user for user assistance. The output of the information can thereby take place by means of an output unit of a user interface of the magnetic resonance device. The output may occur by means of a visual output unit, for example, a monitor and/or a display. The output of the information to the user for user assistance may occur automatically, wherein the output of the information is controlled by the computer unit, as soon as the magnetic resonance unit is identified. The information to the user for user assistance can comprise, for example, a proposal for a scan preview for the pending medical and/or diagnostic magnetic resonance examination on the patient. In addition, the information to the user for user assistance can also comprise, for example, indications for a next step in the workflow and/or operation sequence. In addition, an output of further information deemed by the person skilled in the art to be useful to the user for user assistance is possible at any time. By this means, advantageous assistance can be given to the user. In addition, the user can be reliably guided through the pending medical and/or diagnostic magnetic resonance examination and thus errors during the magnetic resonance examination can also be prevented. In addition thereby, a time-optimized sequence of the medical and/or diagnostic magnetic resonance examination on the patient can be provided.

In an advantageous development of the method, it can be provided that on the basis of the identified magnetic resonance unit, at least one determined scan option is released (e.g. authorized). The releasing of the at least one determined scan option can also take place only after an agreement by the user, for example, by pressing and/or actuating an actuation button. It is also conceivable that the releasing of the at least one determined scan option takes place automatically through the computer unit, as soon as the magnetic resonance unit is identified. The at least one determined scan option can comprise, for example, a license for a determined scan which is correlated with the identified magnetic resonance unit and/or which can be carried out only with the identified magnetic resonance unit. In addition, due to the automated releasing, an automated payment of the at least one determined scan option can take place.

The disclosure further relates to a computer program product and/or executable instructions which comprises a program that may be directly loadable into or otherwise accessed via a memory store (e.g. a non-transitory computer-readable medium) of a programmable computer unit, having program means in order to carry out a method for identifying a magnetic resonance unit with an information unit when the program and/or executable instructions are executed in the computer unit. Thereby, the computer program may utilize the program means, e.g. libraries and auxiliary functions to realize the corresponding functional aspects of the embodiments of the method. The computer program can herein comprise an item of software with a source code, which may still be compiled and linked, or which may only be interpreted, or an executable software code which, for execution, may only be loaded into a corresponding computer unit.

The inventive computer program product may be directly loadable into a memory store of a programmable computer unit and has program code means in order to carry out an inventive method when the computer program product is executed in the computer unit and/or by one or more processors associated with the computer unit. The computer program product can be a computer program or a computer program. In this way, the embodiments of the method can be carried out rapidly, reproducibly, and robustly. The computer program product is configured such that it can carry out the method steps by means of the computer unit. The computer unit may have respective suitable components and/or pre-conditions such as, for example, a suitable working memory store, a suitable graphics card or a suitable logic unit so that the respective method steps can be carried out efficiently. The computer program product may be stored, for example, on a computer-readable medium or deposited on a network or server from where it can be accessed and/or loaded into the processor of a local computer unit, which can be directly connected to, or configured as part of, the magnetic resonance device. Furthermore, control information of the computer program product can be stored on an electronically readable data carrier. The items of control information of the electronically readable data carrier can be configured such that they carry out one or more of the method embodiments as discussed herein when the data carrier is used in a computer unit. Thus, the computer program product can also constitute the electronically readable data carrier. Examples of electronically readable data carriers include non-transitory computer-readable media such as, for instance, are a DVD, a magnetic tape, a hard disk drive or a USB stick, etc., on which electronically readable control information, in particular software (see above) is stored. If this control information (software) is read from the data carrier and stored in a control system and/or a computer unit, each of the embodiments according to the disclosure of the above-described methods can be carried out. The disclosure can therefore also proceed from the aforementioned computer-readable medium and/or the aforementioned electronically readable data carrier.

The disclosure further relates to a computer-readable data carrier which comprises a program which is provided for carrying out a method for identifying a magnetic resonance unit with an information unit.

### BRIEF DESCRIPTION OF THE DRAWINGS/FIGURES

Further advantages, features and details of the disclosure are disclosed in the exemplary embodiment described below by reference to the drawings.

In the drawings:

FIG. 1 is a schematic representation of an example magnetic resonance device having a magnetic resonance unit, in accordance with one or more embodiments of the disclosure;

FIG. 2 is a schematic representation of an example magnetic resonance unit having an information unit, in accordance with one or more embodiments of the disclosure; and

FIG. 3 is a flow diagram of an example method for identifying a magnetic resonance, in accordance with one or more embodiments of the disclosure.

### DETAILED DESCRIPTION

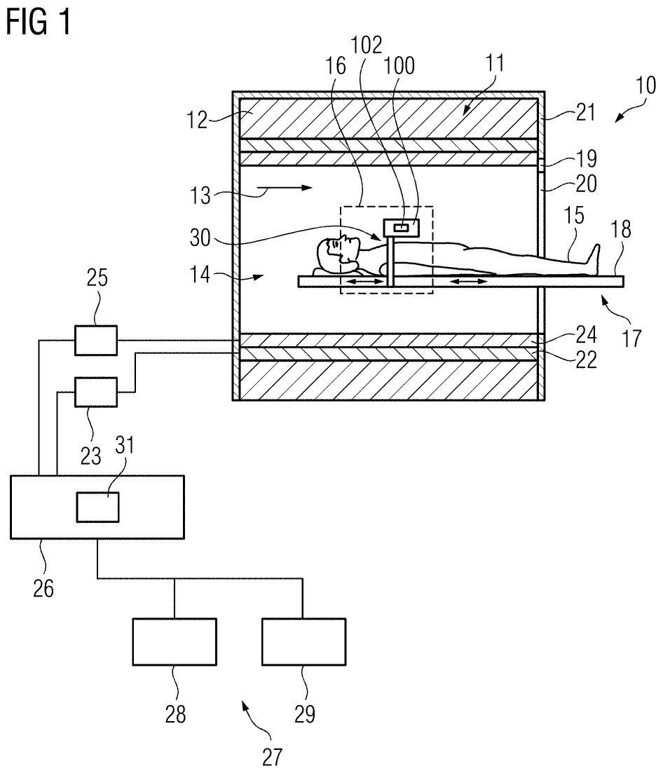

FIG. 1 shows schematically a magnetic resonance device (or imager) 10 according to the disclosure having a magnetic resonance unit 100. The magnetic resonance device 10 comprises a scanner unit 11 formed by a magnet unit which comprises a superconducting main field magnet 12 for generating a strong and, in particular, constant main magnetic field 13. Furthermore, the magnetic resonance device 10 comprises a patient receiving region 14 for receiving a patient 15.

In the present exemplary embodiment, the patient receiving region 14 is configured cylindrical and is surrounded cylindrically in a circumferential direction by the scanner unit 11, in particular the magnet unit. In principle, however, an embodiment of the patient receiving region 14 deviating therefrom is readily conceivable. The FoV 16 (field of view) is arranged within the patient receiving region 14. The FoV 16 of a magnetic resonance device 10 may comprise a region within the patient receiving region 14, wherein this region comprises a main magnetic field 13 that is generated by the main field magnet 12 and is as homogeneous and constant as possible. The isocenter of the magnetic resonance device 10 is arranged within the FoV 16. The isocenter is that region within the patient receiving region 14, in particular of the FoV 16, which has the most homogenous magnetic field, in particular, main magnetic field 13.

The patient 15 can be pushed and/or moved by means of a patient positioning device 17 of the magnetic resonance device 10 into the patient receiving region 14. For this purpose, the patient positioning device 17 has a patient table 18 which is configured to be movable within the patient receiving region 14. For a positioning of the patient positioning device 17, in particular, the patient table 18, within the patient receiving region 14, the magnetic resonance device 10 has a laser positioning unit 19. The laser positioning unit 19 is integrated and/or arranged in a housing 21 of the magnetic resonance device 10 surrounding an introduction opening 20 of the patient receiving region 14.

The scanner unit 11, in particular, the magnet unit also has a gradient coil unit 22 for generating magnetic field gradients that are used for position encoding during an imaging process. The gradient coil unit 22 is controlled by means of a gradient control unit 23 of the magnetic resonance device 10. The scanner unit 11, in particular, the magnet unit, further comprises a high frequency antenna unit 24 for exciting a polarization which forms in the main magnetic field 13 generated by the main field magnet 13. The high frequency antenna unit 14 is controlled by a high frequency antenna control unit 15 of the magnetic resonance device and radiates high frequency magnetic resonance sequences into an examination space which is substantially formed by the patient receiving region 14 of the magnetic resonance device 10.

For controlling the main field magnet 12, the gradient control unit 23 and, for controlling the high frequency antenna control unit 25, the magnetic resonance device 10 has a system control unit 26. The system control unit 26 centrally controls the magnetic resonance device 10, for example, in the execution of a predetermined imaging gradient echo sequence. Furthermore, the system control unit 26 comprises an evaluation unit (not disclosed in greater detail) for evaluating medical image data which is acquired during the magnetic resonance examination.

Furthermore, the magnetic resonance device 10 comprises a user interface 27 which is connected to the system control unit 26. Control information such as, for example, imaging parameters and reconstructed magnetic resonance images can be displayed on an output unit 28, for example, on at least one monitor and/or a display of the user interface 28 for operating medical personnel. In addition, the user interface 27 has an input unit 29 by means of which information and/or parameters can be input by the operating medical personnel during a scanning procedure.

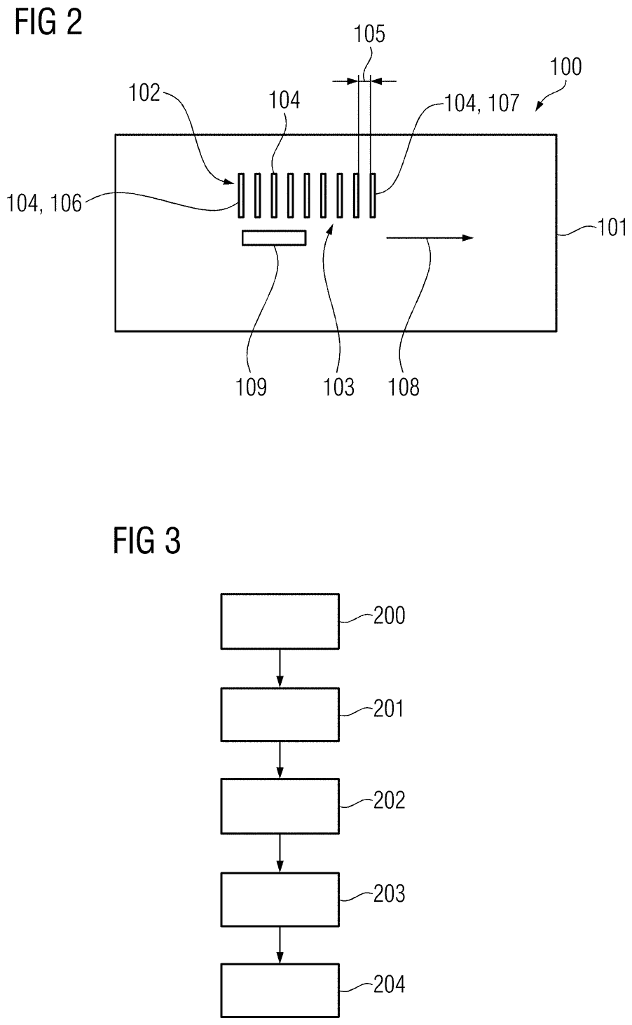

The magnetic resonance device 10 also has a magnetic resonance unit 100, as described below in further detail with reference to FIG. 2. The magnetic resonance unit 100 comprises the holder for an intervention this example, in particular, a needle intervention. Thus, also shown in FIG. 1 is an intervention unit 30, in particular a needle intervention unit. The magnetic resonance unit 100 is arranged on the patient positioning device 17, in particular, on the patient table 18 of the patient positioning device 17.

The magnetic resonance device 10 described can naturally comprise further components that magnetic resonance devices 10 typically have. A general mode of operation of a magnetic resonance device 10 is also known to the person skilled in the art, so that a detailed description of the further components is not included.

FIG. 2 shows schematically an example magnetic resonance unit 100 according to the disclosure. The magnetic resonance unit 100 is configured for use during a medical and/or diagnostic magnetic resonance examination with the medical magnetic resonance device 10 as shown in FIG. 1. In the present exemplary embodiment, the magnetic resonance unit 100 comprises a holder for an intervention, in particular, a needle intervention. In addition, the magnetic resonance unit 100 can also comprise a positioning aid for a patient 15 during a medical and/or diagnostic magnetic resonance examination, in particular, a magnetic resonance radiotherapy examination, and/or a positioning aid, for example, a head clamp, etc.

The use of a special magnetic resonance unit 100 entails the use of a special medical and/or diagnostic magnetic resonance examination, since for the performance of the special medical and/or diagnostic magnetic resonance examination, a special magnetic resonance unit 100 is usually needed. The use of the magnetic resonance unit 100, in particular, the holder is provided only in an intervention, in particular, a needle intervention which is monitored by means of a medical and/or diagnostic magnetic resonance examination.

The magnetic resonance unit 100, in particular the holder, has a housing unit 101 and an information unit 102, wherein the information unit 102 is arranged on the housing unit 101 and may represent a structure representing encoded information. In particular, the information unit 102 is arranged on a surface of the housing unit 101. The information unit 102 is configured so that an item of information of the information unit 102 is acquirable by means of a magnetic resonance sequence of a magnetic resonance scan, in particular, a special determination scan for determining and/or acquiring the information unit 102. By this means, an automatic identification of the magnetic resonance unit 100 is possible, as described in greater detail below in relation to FIG. 3.

The information unit 102 of the magnetic resonance unit 100 comprises a characteristic pattern and/or a characteristic encoding 103. The characteristic pattern and/or the characteristic encoding 103 can comprise, for example, a bar code and/or a QR code. In the present exemplary embodiment, the information unit 102 comprises an encoding 103 configured as a barcode. By means of the encoding and/or the characteristic pattern, an unambiguous recognition and/or identification of the magnetic resonance unit 100 can take place. Thereby, differently configured magnetic resonance units 100 also have different information units, in particular, different characteristic encodings 103 and/or different characteristic patterns.

The information unit 102 may be printed by means of a printing process, in particular a 3D printing process, onto the housing unit 101 of the magnetic resonance unit 100. Thereby, the information unit 102 can comprise a plastics material which is doped with particles made of any suitable conductive and/or metallic components (e.g. iron oxide). By means of the 3D printing process, for example, the plastics material which is doped with the particles of iron oxide is printed on. A structure of a pattern, in particular, a characteristic pattern and/or a structure of an encoding 103, in particular, a characteristic encoding, of the information unit 102 can be specified and/or stipulated. By means of the magnetic resonance scan, in particular, the special determination scan for determining and/or acquiring the information unit 102, the relevant information of the information unit 102, in particular, a characteristic pattern and/or a characteristic encoding 103 becomes visible due to the doping with the particles of iron oxide.

In an alternative embodiment, the information unit 102 can also comprise a channel system with a gadolinium solution. The channel system can thereby also be formed from plastics material, wherein the gadolinium solution is arranged within the channel system. The channel system hereby comprises a closed channel system with a filling opening, in particular a closable filling opening. The channel system can thereby also be applied by means of a 3D printing process onto the housing unit 101 of the magnetic resonance unit 100. A structure of a pattern, in particular, a characteristic pattern and/or a structure of an encoding 103, in particular, a characteristic encoding 103, of the information unit can be defined by the channel system and/or stipulated by means of the channel system. By means of the magnetic resonance scan, in particular, the special determination scan for determining and/or acquiring the information unit 102, the relevant information of the information unit, in particular, a characteristic pattern and/or a characterizing encoding 103, is visible due to the gadolinium solution.

In principle, further embodiments of the information unit 102 deemed useful by a person skilled in the art which enable an acquisition of the characteristic pattern and/or the characteristic encoding 103 by means of a magnetic resonance sequence, in particular, a special determination scan for determining and/or acquiring the information unit 102, are also entirely possible.

The information unit 102 further comprises two or more information elements 104. In the present exemplary embodiment, the information unit 102 comprises more than three information elements 104. A spacing 105 of the individual information elements 104 between two directly adjacent information elements 104 thereby has a minimum spacing. The minimum spacing thereby defines a spacing 105 between the two adjacent information elements 104, so that they can still be acquired in the acquired scan data as two separate information elements 104. The minimum spacing between individual information elements may be any suitable range of values, such as 8 mm 6 mm, 4 mm, 2 mm, 1 mm, etc. The smaller the minimum spacing between the individual information elements 104, the smaller the resolution of the determination scan, in particular the scan sequence of the determination scan, must be, or the scan time for the determination scan must also be extended.

One of the more than three information elements 104 of the information unit 102 comprises a start element 106, and one of the more than three information elements 104 of the information unit 102 comprises a stop element 107. By means of the start element 106 and/or the stop element 107, advantageously a reading direction for acquiring and/or determining the information unit 102 during a magnetic resonance scan, in particular, a special determination scan for determining and/or acquiring the information unit 102 is specified. The start element 106 may comprise an information element 104 which marks the beginning and/or the start of the information unit 102 along a reading direction 108. The reading direction 108 thereby comprises a direction from the start element 106 to the stop element 107. The stop element 107 advantageously comprises an information element 102 which marks the end of the information unit 102 along the reading direction 108. The start element 106 and the stop element 107 may be readable by means of the magnetic resonance scan, in particular, the special determination scan for determining and/or acquiring the information unit 102.

The information unit 102 of the magnetic resonance unit 100 is also visually marked. For this purpose, the information unit 102 comprises a visual marking element 109, in particular, a color marking element. By means of the marking element 109, the information unit 102 is readily visible to a user.

FIG. 3 shows a method for identification of a magnetic resonance unit 100 as described in the statements made with reference to FIGS. 1 and 2, shown together with an information unit 102.

Provided the individual method steps of the method do not have to be performed manually, the method may be executed by a computer unit (or computer, computing unit, computing system, or one or more processors) 31 of the magnetic resonance device 10, wherein the computer unit 31 may be integrated into the system control unit 26. For the control of the method for an identification of a magnetic resonance unit 100, the computer unit 31 may have one or more processors (not disclosed in greater detail). In addition, the computer unit 31 may have software and/or computer programs which are carried out by the processor(s), wherein depending upon the program, individual method steps of the method are carried out automatically. The software and/or computer programs may be stored in a memory store (not disclosed in greater detail). The storage unit can thereby be arranged within the computer unit 31 and/or within the magnetic resonance device 10. In addition, an external arrangement of the software and/or computer programs outside the magnetic resonance device 10 is possible, such as for example, an arrangement of the software and/or computer programs on a cloud. Thereby, the computer unit 31 can access the software and/or computer programs by means of a data connection (not disclosed in greater detail) and/or a data network.

In a first method step 200 of the method for identification of the magnetic resonance unit 100, a positioning of the magnetic resonance unit 100 on the patient positioning device 17, in particular, on the patient table 18, of the magnetic resonance device 10 takes place. The positioning of the magnetic resonance unit 100 on the patient positioning device 17, in particular, on the patient table 18 is carried out manually by the user. Thereby, the magnetic resonance unit 100 is positioned and/or arranged on the patient table 18 such that the magnetic resonance unit 100 is in a position that is ideal and/or optimal for the pending medical and/or diagnostic magnetic resonance examination. The magnetic resonance unit 100 may be positioned together with the patient 15 for the pending medical and/or diagnostic magnetic resonance examination on the patient table 18.

Subsequently, in a second method step 201, a positioning of the patient positioning device 17, in particular, of the patient table 18 within the patient receiving region 14 of the magnetic resonance device 10 takes place such that the information unit 102 of the magnetic resonance unit 100 is arranged within the FoV 16 of the magnetic resonance device 10. Particularly advantageously, the positioning of the patient positioning device 17, in particular, the patient table 18 within the patient receiving region 14 can take place by means of the laser positioning unit 19 of the magnetic resonance device 10. By means of the laser positioning unit 19, the patient positioning device 17, in particular, the patient table 18 is initially positioned such that the information unit 102 of the magnetic resonance unit 100 is arranged directly below the laser positioning unit 19. Subsequently, by means of the laser positioning unit 19, a marking, for example, a cross is projected onto the information unit 102. A control of the patient positioning device 17, in particular, the patient table 18 is adjusted to the laser positioning unit 19 such that subsequently the patient table 18 is moved into the patient receiving region 14 until the information unit 102 of the magnetic resonance unit 100 is arranged within the FoV 16, in particular the isocenter. For this purpose, after the marking by means of the laser positioning unit 19, the user may, for instance, press a positioning button (not disclosed in greater detail) on the patient positioning device 17 and the positioning of the patient table 18 within the FoV takes place automatically by means of the control unit 26 of the magnetic resonance device 10.

Once the information unit 102 of the magnetic resonance unit 100 is arranged within the FoV 16, in particular within the isocenter, of the magnetic resonance device 10, in a third method step 202, a performance of a determination scan to determine and/or acquire the information unit 102 takes place. The execution of the determination scan takes place automatically, controlled by the computer unit 31. Thereby, by means of the scanner unit 11, a magnetic resonance sequence which is specifically designed for acquiring the information unit 102 is carried out. The determination scan takes place temporally before the medical and/or diagnostic magnetic resonance examination on the patient 15, which is performed only after the identification of the magnetic resonance unit 100. By means of the determination scan, determination scan data is acquired and passed on the computer unit 31 for evaluation.

After the performance of the determination scan, in a fourth method step 203, an evaluation of the determination scan data takes place, wherein on the basis of the determination scan data, the magnetic resonance unit 100 is identified. The evaluation of the determination scan data is carried out automatically by means of the computer unit 31.

The evaluation of the determination scan data can thereby take place by means of an evaluation algorithm of the computer unit 31. The evaluation algorithm may comprise a pattern recognition algorithm. The evaluation algorithm, in particular, the pattern recognition algorithm is carried out automatically by the computer unit 31, in particular, the processor of the computer unit 31, during an evaluation of the determination scan data. The evaluation algorithm, in particular, the pattern recognition algorithm, can also be carried out by means of machine learning, wherein in this regard, the machine learning may be implemented via the computer unit 31. By means of the evaluation algorithm, in particular, the pattern recognition algorithm, a characteristic pattern and/or a characteristic encoding 103 of the information unit 102 of the magnetic resonance unit 100 can be identified.

In the fourth method step 203 of the evaluation of the determination data, in addition, an identification of the magnetic resonance unit 100 by means of a comparison of a determined characteristic pattern and/or a determined characteristic encoding 103 with patterns and/or encodings stored in a database can also take place. The database may comprise an allocation of all the magnetic resonance units 100 that are available with the corresponding characteristic patterns and/or the characteristic encodings 103. On the basis of the comparison with the characteristic patterns and/or the characteristic encodings stored in the database, subsequently, the magnetic resonance unit 100 is unambiguously identified. The comparison of the determined characteristic pattern and/or the determined characteristic encoding 103 with the characteristic patterns and/or the characteristic encodings stored in the database and the subsequent identification of the magnetic resonance unit 100 is performed automatically by means of the computer unit 31.

The database with the stored characteristic patterns and/or characteristic encodings can be included by the computer unit 31. In addition, the database with the stored characteristic patterns and/or characteristic encodings can also be included separately from the computer unit 31, by the magnetic resonance device 10, however. The database with the stored characteristic patterns and/or the characteristic encodings can however also be formed separately from the magnetic resonance device 10, wherein a data transmission by means of a data transmission unit and/or a data transmission network can take place between the computer unit 31 and the database.

If an identification of the magnetic resonance unit 100 by the computer unit 31 has taken place, then determined and/or defined magnetic resonance examinations which usually comprise at least one pre-determined sequence and/or pre-determined magnetic resonance scans are also associated with the magnetic resonance unit 100. This information can also be stored in the database and accessed on identification of the magnetic resonance unit 100.

On the basis of the identified magnetic resonance unit 100, subsequently, in an optional fifth method step 204, an item of information can be output to a user for user assistance. The output of the information can thereby take place by means of an output unit 28 of the user interface 27 of the magnetic resonance device 10. The output may occur by means of a visual output unit 28, for example, a monitor and/or a display. The output of the information to the user for user assistance may take place automatically, wherein the output of the information is controlled by the computer unit 31, as soon as the magnetic resonance unit 100 is identified. The information to the user for user assistance can comprise, for example, a proposal for a scan preview for the pending medical and/or diagnostic magnetic resonance examination on the patient 15. In addition, the information to the user for user assistance can also comprise, for example, indications for a next step in the workflow and/or safety information for the pending medical and/or diagnostic magnetic resonance examination.

In an advantageous development of the method, it can be provided, in the fifth method step 204, that on the basis of the identified magnetic resonance unit 100, at least one determined scan option is released (e.g. authorized). The releasing of the at least one determined scan option can also take place only after an agreement by the user for example. It is also conceivable that the releasing of the at least one determined scan option takes place automatically by means of the computer unit 31, as soon as the magnetic resonance unit 100 and the medical and/or diagnostic magnetic resonance examination to be carried out with the magnetic resonance unit 100 is identified. The at least one determined scan option can comprise, for example, a license for a determined scan which is correlated with the identified magnetic resonance unit 100 and/or which can be carried out only with the identified magnetic resonance unit 100. In addition, due to the automated releasing, an automated payment of the at least one determined scan option can take place.

Although the disclosure has been illustrated and described in greater detail with the exemplary embodiments, the disclosure is not restricted by the examples disclosed and other variations can be derived therefrom by the person skilled in the art without departing from the protective scope of the disclosure.

The various functional blocks, apparatuses, modules, units, components of physical or functional units, etc., as shown in the drawings and described herein may be implemented as any suitable number and type of computer processors, hardware components, the execution of software algorithms, or combinations thereof, and thus may alternatively be referred to as a “unit,” “system,” “circuitry,” or a “device.”

What is claimed is:

1. A magnetic resonance imager configured for using during a magnetic resonance examination, comprising:
high frequency antenna circuitry configured to radiate a magnetic resonance sequence into an examination space of the magnetic resonance imager;
a medical magnetic resonance device having a housing upon which a structure is arranged; and
one or more processors configured to acquire information encoded in the structure via the radiated magnetic resonance sequence.

2. The magnetic resonance imager as claimed in claim 1, wherein the structure comprises a characteristic pattern that represents encoded information.

3. The magnetic resonance imager as claimed in claim 1, wherein the structure is printed onto the housing.

4. The magnetic resonance imager as claimed in claim 1, wherein the structure comprises a polymer material that is doped with metallic particles.

5. The magnetic resonance imager as claimed in claim 4, wherein the metallic particles are made of iron oxide.

6. The magnetic resonance imager as claimed in claim 1, wherein the structure comprises a channel system including a gadolinium solution.

7. The magnetic resonance imager as claimed in claim 1, wherein the structure comprises two or more information elements, with at least two of the information elements being spaced apart by a predetermined spacing.

8. The magnetic resonance imager as claimed in claim 1, wherein the structure includes at least one of a start information element and a stop information element.

9. The magnetic resonance imager as claimed in claim 1, wherein the structure includes a visual marking.

10. A method for identifying a medical magnetic resonance device having a structure positioned thereon, comprising:
positioning the medical magnetic resonance device on a patient positioning device of a magnetic resonance imager;
positioning the patient positioning device within a patient receiving region of the magnetic resonance imager such that a structure of the medical magnetic resonance device is arranged within a field of view (FOV) of the magnetic resonance imager;
executing a determination scan within the FOV to generate determination scan data;
evaluating the determination scan data to acquire information encoded in the structure; and
identifying the medical magnetic resonance device based upon the acquired information.

11. The method according to claim 10, wherein the positioning of the patient positioning device takes place within the patient receiving region by means of a laser positioner.

12. The method as claimed in claim 10, wherein the evaluating of the determination scan data includes the use of an evaluation algorithm that identifies at least one of a corresponding pattern and a corresponding encoding associated with the structure.

13. The method as claimed in claim 12, wherein the identification of the medical magnetic resonance device comprises comparing at least one of the determined pattern and the determined encoding with at least one of a predetermined pattern and a predetermined encoding, respectively, stored in a database.

14. The method as claimed in claim 10, further comprising:
outputting, on the basis of the identified medical magnetic resonance device, information to a user.

15. The method as claimed in claim 10, further comprising:
authorizing, prior to performing the determination scan, at least one option associated with the determination scan.

16. A non-transitory computer readable medium having instructions stored thereon that, when executed by one or more processors of a magnetic resonance imager, cause the magnetic resonance imager to:
radiate, via high frequency antenna circuitry, a magnetic resonance sequence into an examination space of the magnetic resonance imager; and
acquire, via the radiated magnetic resonance sequence, information encoded in a structure of a medical magnetic resonance device having a housing upon which the structure is arranged.
